(19) United States
(12) Patent Application Publication
(10) Pub. No.: US 2004/0173845 A1
(43) Pub. Date: Sep. 9, 2004

(54) Semiconductor device having trench gate structure and method for manufacturing the same

(75) Inventor: Takaaki Aoki, Okazaki-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/790,211

(22) Filed: Mar. 2, 2004

(30) Foreign Application Priority Data
Mar. 3, 2003 (JP) 2003-55759

(51) Int. Cl. H01L 21/8236

(52) U.S. Cl. 257/329

(57) ABSTRACT

A method for manufacturing a semiconductor device includes the steps of: forming a trench in a substrate; forming a conductive film in the trench through an insulation film; and annealing the substrate at an annealing temperature after the step of forming the conductive film so that a damage in the insulation film is removed at the annealing temperature. The device

[symbol]

### CROSS REFERENCE TO RELATED APPLICATION

This application is based on Japanese Patent Application No. 2003-55759 filed on Mar. 3, 2003, the disclosure of which is incorporated herein by reference.

### FIELD OF THE INVENTION

The present invention relates to a semiconductor device having a trench gate structure and a method for manufacturing the same.

### BACKGROUND OF THE INVENTION

A semiconductor device having a trench gate structure (i.e., trench gate type semiconductor device) is used for, for example, a trench gate type power device such as a diffused metal-oxide semiconductor (i.e., DMOS) transistor and an insulated gate bipolar transistor (i.e., IGBT). The trench gate type semiconductor device includes a trench formed in a semiconductor substrate. An insulation film is formed on an inner wall of the trench, and a conductive film is embedded in the trench through the insulation film.

The trench gate type power device is disclosed, for example, in Japanese Unexamined patent Application Publications No. 2001-196587, No.2001-127072 and No. 2001-127284. The device has a microscopic gate structure having a trench, so that the device has high-density cells. Therefore, an ON-state resistance of the device is reduced. Further, a manufacturing cost for manufacturing the device is also decreased.

However, the trench gate type power device has a problem with reliability. The problem is that the insulation film, i.e., the gate insulation film has a short lifetime because of a time dependent dielectric breakdown (i.e., TDDB) as compared with a planar gate type power device. The planar gate type power device has a gate electrode formed parallel to a surface of a substrate. It is considered that the problem is, for example, caused by following reasons. Firstly, a damage layer is disposed in the inner wall of the trench. The damage layer is formed in an etching process for forming the trench. Secondary, a large stress is generated near an upper side of the trench or a lower side of the trench. The large stress is generated by volume expansion during a manufacturing process. Thirdly, a crystalline defect is easily generated near the upper side or the lower side of the trench. The damage, stress or defect is disposed in the inner wall of the trench, so that the gate insulation film formed on the inner wall of the trench deteriorates. Therefore, the lifetime of the gate insulation film is reduced. That is, the reliability of the gate insulation film is reduced. Thus, the device has low reliability.

In view of the above problem, a sacrificial oxidation method is performed to improve the damage, the stress or the defect of the inner wall of the trench. The sacrificial oxidation method is such that the inner wall of the trench is oxidized to form an oxidation film on the inner wall after the trench is formed, and then the oxidation film on the inner wall is removed so as to improve the deterioration of the inner wall. The sacrificial oxidation method can improve the deterioration of the inner wall caused by the damage layer disposed in the inner wall. However, the sacrificial oxidation method does not sufficiently improve the deterioration of the inner wall caused by the stress or the crystalline defect near the trench. Therefore, further improvement of the reliability of the gate insulation film is necessitated.

### SUMMARY OF THE INVENTION

In view of the above-mentioned problems, it is an object of the present invention to provide a semiconductor device having a trench gate. Specifically, the device has high reliability.

It is another object of the present invention to provide a method for manufacturing a semiconductor device having a trench gate.

A method for manufacturing a semiconductor device includes the steps of: forming a trench in a substrate; forming a conductive film in the trench through an insulation film; and annealing the substrate at an annealing temperature after the step of forming the conductive film so that a damage in the insulation film is removed at the annealing temperature.

The device manufactured with the above method has high reliability. That is because the damage such as a distortion in the insulation film is relaxed, i.e., removed. The damage is caused by, for example, a stress and a crystalline defect generated near the trench. Thus, the reliability of the insulation film is improved, so that the device has high reliability.

Preferably, the substrate is made of silicon, and the annealing temperature is equal to or higher than 1150° C. More preferably, the conductive film is made of doped poly crystalline silicon, and the insulation film is made of silicon oxide and silicon nitride. Furthermore preferably, the insulation film includes an oxide-nitride-oxide film and upper and lower oxide films, and the trench includes a sidewall and upper and lower portions. The oxide-nitride-oxide film is disposed on the sidewall of the trench, the upper oxide film is disposed on the upper portion of the trench, and the lower oxide film is disposed on the lower portion of the trench. The oxide-nitride-oxide film includes a silicon oxide film, a silicon nitride film and a silicon oxide film. The upper and lower oxide films are made of silicon oxide.

More preferably, the method further includes the step of: forming a source region having a contact surface between the source region and the substrate, which is disposed near the trench and is almost parallel to the substrate. The conductive film in the trench provides a gate electrode. The gate electrode includes a canopy for covering the upper oxide film so that the gate electrode has a T-shaped cross section. The canopy of the gate electrode has an edge, which is disposed at a predetermined distance from an edge of an opening of the trench. The predetermined distance is predetermined not to prevent the source region from forming.

Furthermore preferably, the device includes a cell region and a gate lead wire region. The cell region includes a plurality of cells, each of which works as a transistor and has a hexagonal shape, and the gate lead wire region includes a gate lead wire. Further, the transistor is an N channel type MOSFET, a P channel type MOSFET or an IGBT.

Further, a method for manufacturing a semiconductor device includes the steps of: forming a trench having an inner wall in a substrate; forming an insulation film on the inner wall of the trench; forming a gate electrode in the trench through the insulation film; implanting an impurity into the substrate with using the gate electrode as a mask after the step of forming the gate electrode; performing a thermal diffusion process for diffusing the impurity so that a source region adjacent to the trench and disposed on a surface of the substrate is formed; and annealing the substrate at an annealing temperature after the step of forming the conductive film so that a distortion in the insulation film is removed at the annealing temperature. The device manufactured with the above method has high reliability.

Preferably, the thermal diffusion process is performed at a process temperature, and the annealing temperature in the step of annealing is higher than the process temperature in the step of performing the thermal diffusion process. More preferably, the distance between the edge of the canopy and the edge of the opening of the trench is in a range between 0.05 μm and 0.1 μm. Furthermore preferably, the annealing temperature in the step of annealing is equal to or higher than 1150° C., and the substrate is annealed in an inert gas atmosphere in the step of annealing.

Furthermore, a semiconductor device having a trench gate structure includes a semiconductor substrate having a trench with an inner wall disposed in the substrate; an insulation film disposed on the inner wall of the trench; a gate electrode disposed in the trench through the insulation film; and a source region adjacent to the trench and disposed on a surface portion of the substrate. The insulation film does not include a distortion therein. The device has high reliability.

### BRIEF DESCRIPTION OF THE DRAWINGS

The above and other objects, features and advantages of the present invention will become more apparent from the following detailed description made with reference to the accompanying drawings. In the drawings:

FIG. 1 is a plan view showing a semiconductor device according to a preferred embodiment of the present invention;

FIG. 2 is a cross-sectional view taken along line II-II in FIG. 1;

FIG. 3 is a cross-sectional view taken along line III-III in FIG. 1;

FIG. 4 is a cross-sectional view taken along line IV-IV in FIG. 1;

FIG. 5 is a cross-sectional view taken along line V-V in FIG. 1;

FIG. 6 is a cross-sectional view taken along line VI-VI in FIG. 1;

FIGS. 7A-7C are schematic cross sectional view explaining a method for manufacturing the semiconductor device according to the preferred embodiment;

FIGS. 8A-8C are schematic cross sectional view explaining the method for manufacturing the semiconductor device according to the preferred embodiment;

FIGS. 9A-9C are schematic cross sectional view explaining the method for manufacturing the semiconductor device according to the preferred embodiment;

FIGS. 10A-10C are schematic cross sectional view explaining the method for manufacturing the semiconductor device according to the preferred embodiment;

FIGS. 11A-11C are schematic cross sectional view explaining the method for manufacturing the semiconductor device according to the preferred embodiment;

FIG. 12 is a graph showing a relationship between cumulative failure rate and fault time in various devices, according to the preferred embodiment;

FIG. 13 is a graph showing the relationship between the cumulative failure rate and the fault time in various devices, according to the preferred embodiment;

FIG. 14A is a graph showing a process temperature in each process of the method for manufacturing the device, FIG. 14B is a graph showing a stress in various devices, and FIG. 14C is a graph showing a density of crystalline defect in various devices, according to the preferred embodiment; and

FIG. 15A is a graph showing a relationship between a process temperature and the stress, and FIG. 15B is a graph showing a relationship between the process temperature and the density of crystalline defect, according to the preferred embodiment.

### DETAILED DESCRIPTION OF THE PREFERRED EMBODIMENT

The inventor has preliminarily studied about a stress and a crystalline defect, which are disposed in an inner wall of a trench in a trench gate type semiconductor device. The stress and the crystalline defect are thought to attribute reliability of an insulation film formed on the inner wall of the trench. Specifically, the inventor has studied when the stress and the crystalline defect are generated during a manufacturing process of the device.

The stress and the crystalline defect are generated near the trench after a conductive film is formed (i.e., embedded) in the trench through the insulation film. Therefore, it is considered that a strain (i.e., a distortion) is generated in the insulation film by the stress and/or the crystalline defect. Thus, the reliability of the insulation film is reduced.

The above consideration is also applied to another trench gate type semiconductor device with a conductive film formed in a trench through an insulation film and another semiconductor device with a trench capacitor, which is provided such that an upper electrode is formed in a trench through an insulation film. In view of the above consideration, a preferred embodiment of the present invention is described as follows.

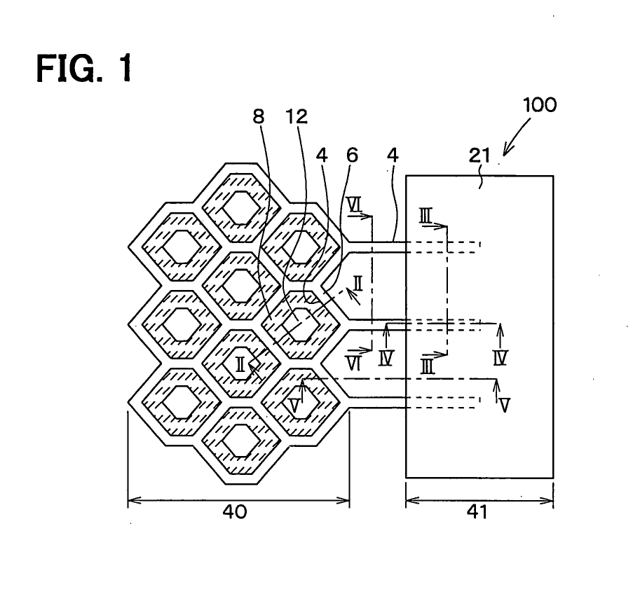

A trench gate type semiconductor device 100 according to a preferred embodiment of the present invention is used for a diffused metal-oxide semiconductor (i.e., DMOS) transistor. The device 100 has a construction, as shown in FIGS. 1-6. As shown in FIG. 1, the device 100 includes a cell region 40 and a gate lead wire region 41. In the cell region 40, multiple cells are formed, and each cell works as a transistor. In the gate lead wire region 41, a gate lead wire is formed. In the cell region 40, a trench gate having a mesh structure is formed. The mesh structure includes multiple meshes having a substantially hexagonal shape. Each mesh has the same shape.

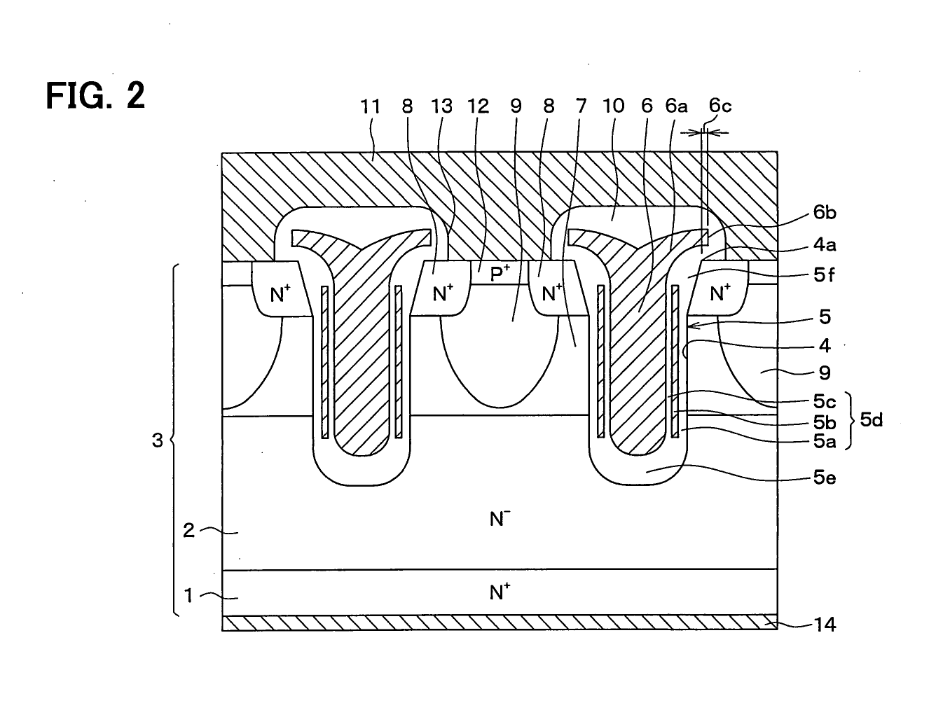

As shown in FIG. 2, the device 100 includes a semiconductor substrate 3 having a N⁺ type silicon layer 1 and a N⁻ type drift layer 2. The N⁺ type silicon layer 1 is made of silicon, and has N type conductivity. The N⁻ type drift layer 2 is disposed on the N⁺ type silicon layer 1. In the cell region, a trench 4 is formed on one surface of the substrate 3 (i.e., on a foreside surface of the substrate 3). The trench 4 has a depth of, for example, 1-3 μm. A gate insulation film 5 is formed on an inner wall of the trench 4.

The gate insulation film 5 includes an upper oxide film 5f, an oxide-nitride-oxide film (i.e., an ONO film) 5d and a lower oxide film 5e. The ONO film 5d is disposed on a sidewall of the trench 4. The ONO film 5d includes a bottom oxide film 5a made of silicon oxide film, a silicon nitride film 5b and a top oxide film 5c made of silicon oxide film. The upper oxide film 5f is disposed on an upper portion of the trench 4, and the lower oxide film 5e is disposed on a lower portion of the trench 4. Both of the upper and lower oxide films 5e, 5f are thicker than the ONO film 5d, and are made of silicon oxide film.

A gate electrode 6 is disposed in the trench 4 through the gate insulation film 5. The gate electrode 6 is made of poly crystalline silicon. The gate electrode 6 has a cross-section of T-shape. When seen from an overhead view of the substrate 3, the gate electrode 6 covers the upper oxide film 5f of the gate insulation film 5. Part of the gate electrode 6 extrudes upward from the surface of the substrate 3. The part of the gate electrode 6 is a canopy 6a of the gate electrode 6.

In the substrate 3, a P type region 7 for providing a channel, a N⁺ type region 8 for providing a source and a P type body region 9 are disposed between two trenches 4. An interlayer insulation film 10 is disposed on the gate electrode 6 and the substrate 3. The interlayer insulation film 10 is made of BPSG (i.e., boro-phosphosilicate).

A metal film 11 is formed on the interlayer insulation film 10. The metal film 11 is made of aluminum (i.e., Al), and works as a source electrode. The interlayer insulation film 10 has a contact hole 13, which is disposed on the N⁺ type region 8 and the P⁺ type region 12. The metal film 11 electrically connects to the N⁺ type region 8 and the P⁺ type region 12 through the contact hole 13. Another metal film 14 for providing a drain electrode is formed on the backside of the substrate 3, i.e., on the N⁺ silicon layer 1. The metal film 14 is made of, for example, aluminum.

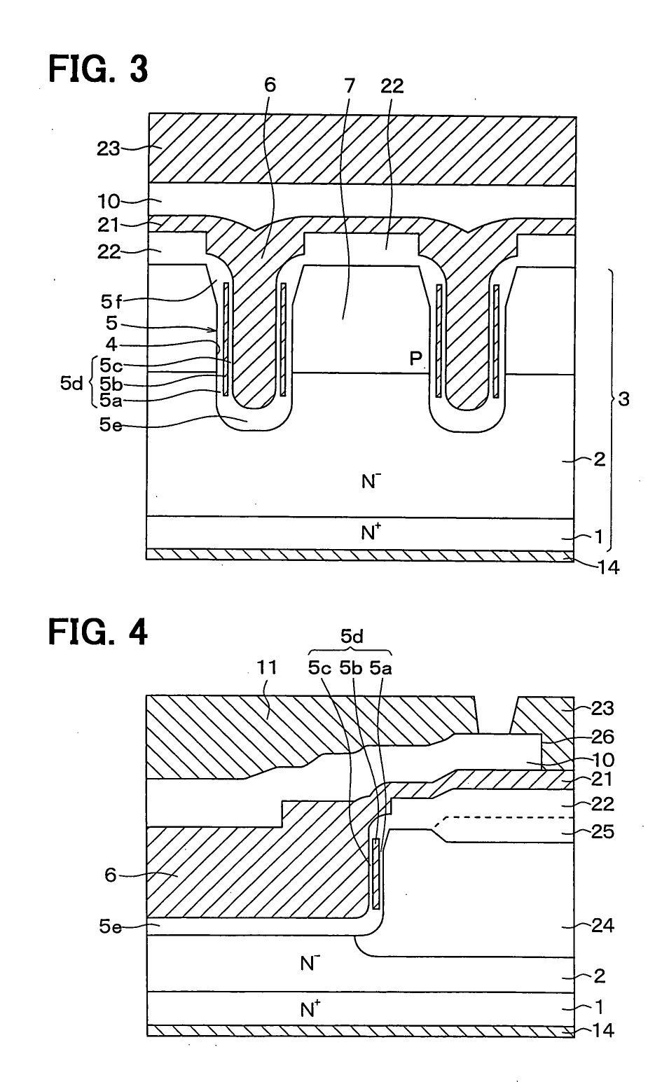

As shown in FIGS. 1 and 3, the trench 4 extends from the cell region 40 to the gate lead wire region 41. In the gate lead wire region 41, the trench 4 is formed on the foreside of the substrate 3, and has a depth of, for example, 1-3 μm. In the gate lead wire region 41, the gate insulation film 5 is formed on the inner wall of the trench 4. This is the same construction as the trench 4 in the cell region 40. The gate electrode 6 made of poly crystalline silicon is formed (i.e., embedded) in the trench 4 through the gate insulation film 5.

An oxide film 22 is disposed on the substrate 3, and disposed in a region except for the gate electrode 6. The oxide film 22 is prepared in such a manner that the oxide film 22 as a mask for forming the trench 4 is not removed from the substrate 3 even after the trench 4 is formed. The film thickness of the oxide film 22 is 0.8-1.0 μm. A gate lead wire 21 is formed on the oxide film 22 so as to connect to the gate electrode 6, and is made of poly crystalline silicon. The interlayer insulation film 10 extends from the cell region 40 to the gate lead wire region 41 so that the interlayer insulation film 10 is formed on the gate lead wire 21. A metal film 23 is formed on the interlayer insulation film 10, and is made of, for example, aluminum. The metal film 14 for providing the drain electrode is formed on the backside of the substrate 3.

In the cell region 40, the N⁺ type region 8 is disposed on the P type region 7, and adjacent to the trench 4, as shown in FIG. 2.

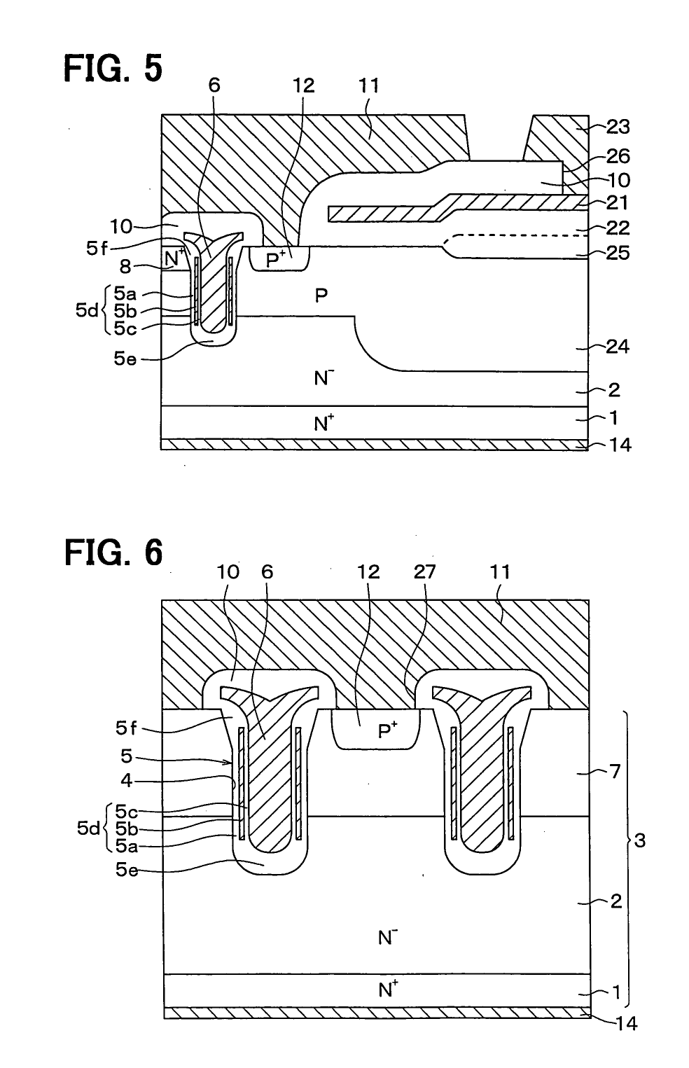

As shown in FIGS. 4 and 5, a P type well layer 24 is formed on the N⁻ drift layer 2 so that the P type well layer 24 continuously connects to the P type region 7 in the cell region 40. An oxide film 25 as a field insulation film is formed on the P type well layer 24 with using the LOCOS method (i.e., the local oxidation of silicon method). The oxide film 22 is formed on the oxide film 25. The gate lead wire 21 is also formed on the P type well layer 24 through the oxide films 22, 25. The metal film 23 for providing the gate electrode 6 electrically connects to the gate lead wire 21 through a contact hole 26 formed in the interlayer insulation film 10.

As shown in FIGS. 4-6, the P⁺ type region 12 is formed in a middle region between the cell region 40 and the gate lead wire region 41. The middle region does not include the cell, so that the P type body region 9 and the N+ type region 8 are not formed on the P type region 7 in the middle region. This construction is different from that in the cell region 40. However, the P type body region 9 and the N⁺ type region 8 may be formed on the P type region 7 in the middle region. The P⁺ type region 12 electrically connects to the metal film 11 through the contact hole 27 formed on the interlayer insulation film 10.

In the above device 100, a predetermined voltage is applied to the gate electrode 6 so that the device 100 becomes an ON-state. Then, a region around the trench 4, which is disposed on the P type region 7, becomes a channel region. Thus, a current flows between the source and the drain through the channel region.

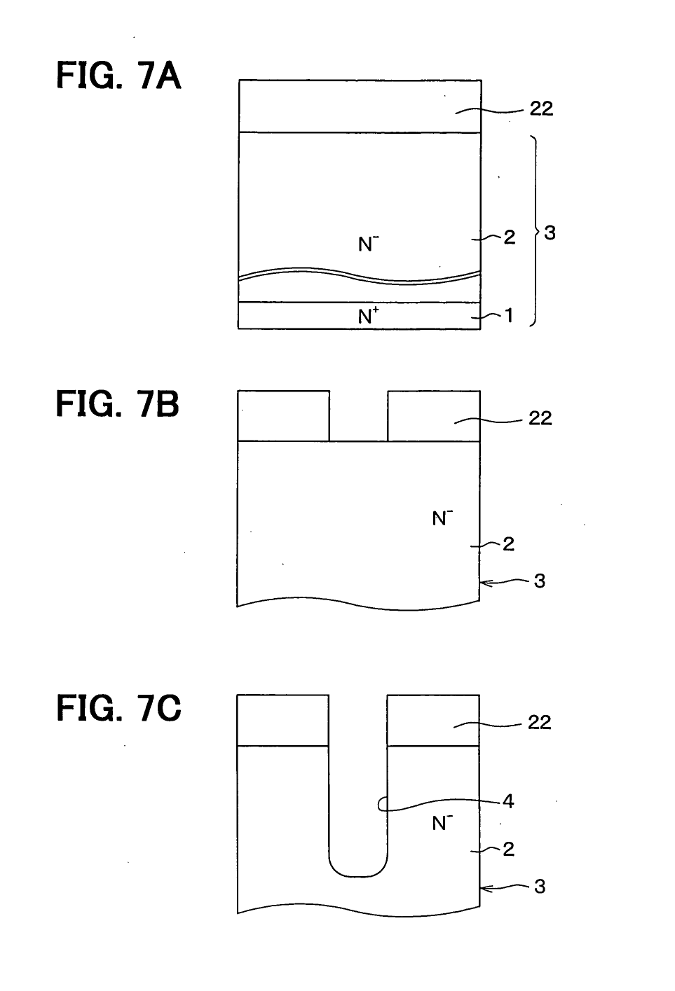

The device 100 is manufactured as follows. FIGS. 7A-11C show the cross section of the device in the cell region 40, which is a half view of the device shown in FIG. 2.

As shown in FIG. 7A, the semiconductor substrate 3 is prepared. The substrate 3 includes the N⁺ silicon layer 1 having a crystal plane of (100). On the N⁺ silicon layer 1, the N⁻ drift layer 2 is formed with using an epitaxial growth method. Then, the oxide film 22 is formed on the substrate 3 with using the CVD (i.e., the chemical vapor deposition) method. The film thickness of the oxide film 22 is about 1 μm. The oxide film 22 is used for a mask in a case where the trench 4 is formed in a latter process.

As shown in FIGS. 7B and 7C, part of the oxide film 22 disposed on a trench-to-be-formed region is selectively removed with using the photolithography method and the dry-etching method. Then, the surface of the substrate 3 is dry-etched with using the oxide film 22 as a mask, which is patterned into a predetermined pattern, so that the trench 4 is formed in the substrate 3.

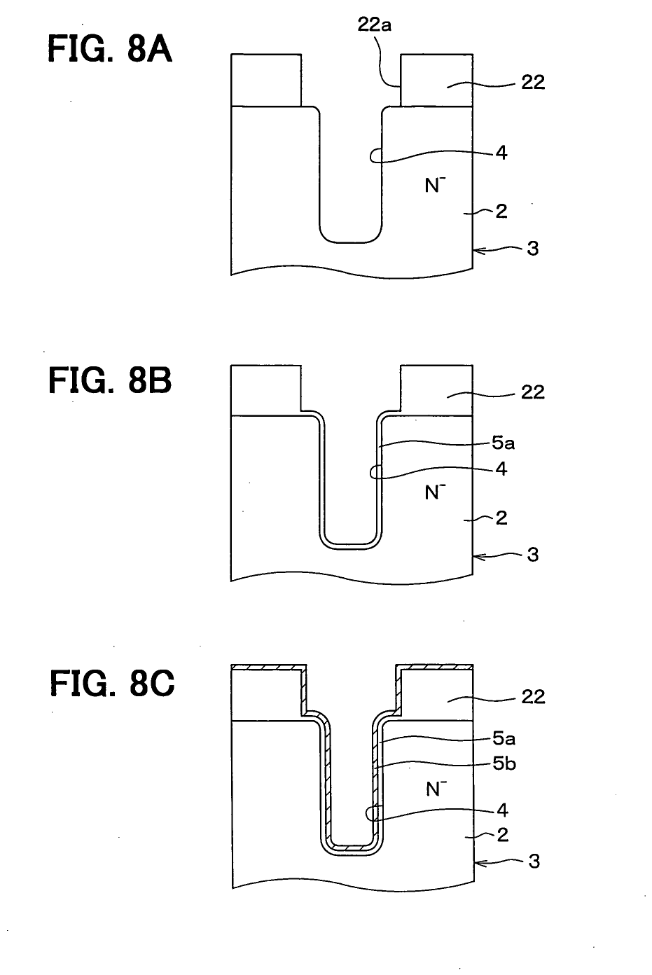

The inner wall of the trench 4 is damaged in the above process, in which the trench 4 is formed. The damage caused by the trench etching is eliminated in the following process. As shown in FIG. 8A, the inner wall of the trench 4 is chemically etched, and then the substrate 3 is annealed at about 1000° C. After that, the substrate is thermally oxidized at 850-1050° C. so as to process the sacrificial oxidation. At that time, the upper and lower portions of the trench 4 are rounded. Specifically, a corner of the trench 4 is rounded. Further, an opening of the oxide film 22 for forming the trench 4 becomes larger. Specifically, a side edge 22a of the opening of the oxide film 22 is cut back so that the opening is enlarged.

As shown in FIGS. 8B and 8C, the gate insulation film 5 is formed. At first, the substrate 3 is annealed at 850° C. in an atmosphere of oxygen O₂ or moisture H₂O, so that the substrate 3 is oxidized. Therefore, a silicon oxide film as the bottom oxide film 5a is formed on the inner wall of the trench 4. Then, the silicon nitride film 5b is formed on the bottom oxide film 5a and the oxide film 22 with using the LPCVD (low pressure chemical vapor deposition) method.

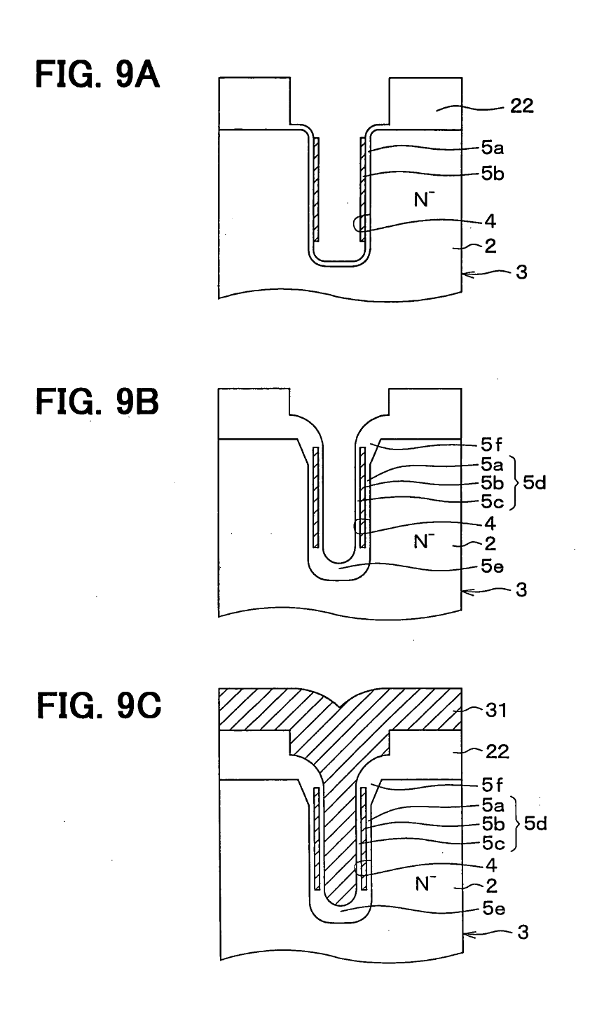

As shown in FIG. 9A, part of the silicon nitride film 5b is etched and removed with using the anisotropic dry etching method with CHF₃ and O₂ gas system so that a bottom part of the silicon nitride film 5b, which is disposed on the bottom of the trench 4, is removed. Thus, the silicon nitride film 5b disposed on the sidewall of the trench 4 remains, and the bottom part of the silicon oxide film, i.e., the bottom oxide film 5a is exposed. At that time, parts of the silicon nitride film 5b disposed on the upper portion of the trench 4 and disposed on the oxide film 22 are removed simultaneously, so that the silicon oxide film, i.e., the bottom oxide film 5a is exposed from the upper portion of the trench 4 and the oxide film 22.

As shown in FIG. 9B, the substrate 3 is annealed at 950° C. in the atmosphere of oxygen O₂ or moisture H₂O, so that the substrate 3 is thermally oxidized. Thus, the top oxide film 5c as the silicon oxide film is formed on the silicon nitride film 5b. Thus, on the sidewall of the trench 4, the ONO film 5d is formed. The ONO film 5d is composed of the bottom oxide film 5a, the silicon nitride film 5b and the top oxide film 5c. On the upper portion and lower portion, i.e., the bottom of the trench 4, the upper and lower oxide films 5e, 5f are formed by the above thermal oxidation process. The upper and lower oxide films 5e, 5f are thick, so that an electric field concentration at the corner of the upper and lower portions of the trench 4 is suppressed, i.e., the electric field intensity around the corner is suppressed to increase. Therefore, a reduction of a withstand voltage of the device 100 caused by the electric field concentration is limited. Specifically, the electric field concentration is mainly applied to the gate insulation film 5 at the corner of the trench 4.

As shown in FIG. 9C, a doped poly crystalline silicon film 31 is formed in the trench 4 and on the substrate 3 with using the LPCVD method, so that the trench 4 is filled with the doped poly crystalline silicon film 31. The film thickness of the doped poly crystalline silicon film 31 disposed on the oxide film 22 is, for example, about 1 μm. Although the doped poly crystalline silicon film 31 is directly deposited in the trench 4 and on the substrate 3, a non-doped poly crystalline silicon film can be formed firstly and then an impurity as a dopant is doped in the non-doped poly crystalline silicon film so that the doped poly crystalline silicon film 31 is formed.

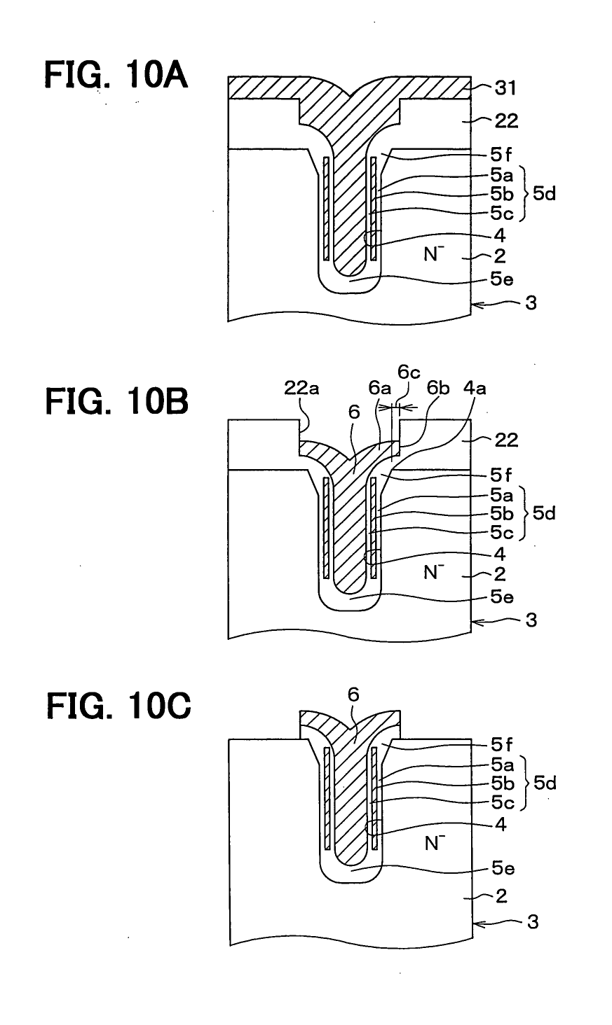

As shown in FIG. 10A, the doped poly crystalline silicon film 31 is thinned by etch back process so that the film thickness of the doped poly crystalline silicon film 31 becomes a predetermined thickness. Specifically, the film thickness of the doped poly crystalline silicon film 31 disposed on the oxide film 22 becomes, for example, 0.3-0.5 μm. This thinning of the doped poly crystalline silicon film 31 provides for forming the gate lead wire 21.

As shown in FIG. 10B, the doped poly crystalline silicon film 31 is further etched with using the photolithography and dry etching method. Thus, in the cell region 40, a height of the doped poly crystalline silicon film 31 is equal to or lower than the surface of the oxide film 22, and is higher than the surface of the substrate 3. Specifically, an etching time is controlled so that the height between the upper surface of the doped poly crystalline silicon film 31 and the surface of the substrate 3 is, for example, 0.6-0.7 μm. And, in the gate lead wire region 41, the doped poly crystalline silicon film 31 disposed on the oxide film 22 is not etched, (i.e., remains), as shown in FIG. 3. Thus, the gate electrode 6 is formed in the cell region 40, and the gate lead wire 21 is formed in the gate lead wire region 41. Here, the side edge 22a of the opening of the oxide film 22 is cut back so that the opening is enlarged. Therefore, the gate electrode 6 is formed to have the T-shaped cross section, and the canopy 6a of the gate electrode 6 has the film thickness of 0.3-0.5 μm.

In this embodiment, the side edge 22a of the oxide film 22 is set to be a predetermined position so as to form the following construction. The canopy 6a of the gate electrode 6 covers the upper oxide film 5f disposed inside of an opening 4a of the trench 4. Specifically, the canopy 6a covers the upper surface of the upper oxide film 5f. And a length 6c between an edge 6b of the canopy 6a and an edge of the opening 4a of the trench 4 is prepared so as to form the N⁺ type region 8 in a latter process of forming a source region. The N⁺ type region 8 as a source region contacts the P type region 7 so that a contact surface 8a between the N⁺ type region 8 and the P type region 7 disposed near the trench 4 is almost parallel to the surface of the substrate 3.

Specifically, the length 6c between the edge 6b of the canopy 6a and the edge of the opening 4a of the trench 4 becomes in a range between 0.05 μm and 0.1 μm when a trench mask is removed in the latter process described latter. Here, the length 6c is parallel to the surface of the substrate 3.

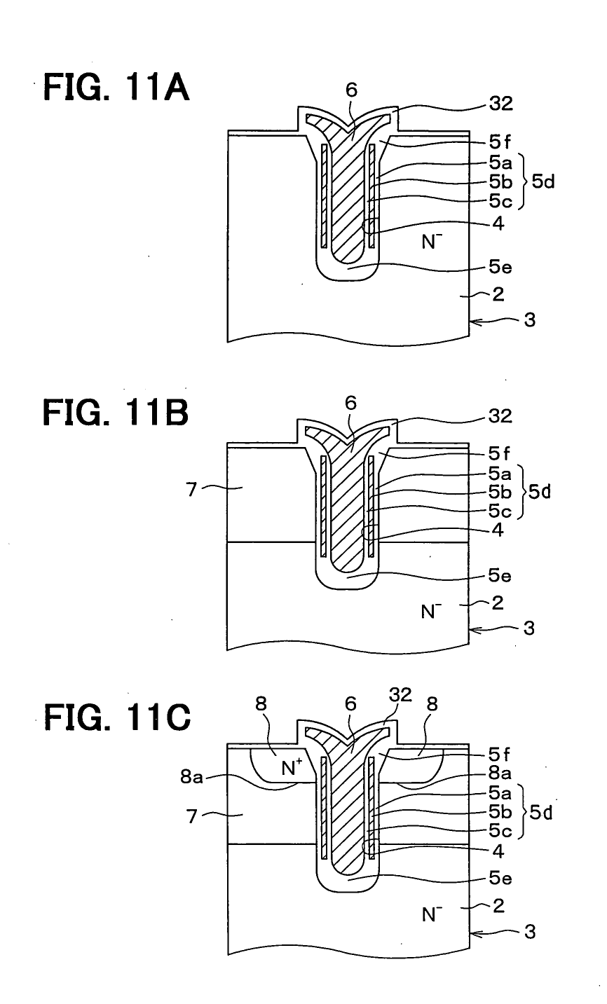

As shown in FIGS. 10C and 11A, the oxide film 22 disposed in the cell region 40 is removed. The oxide film 22 is used as a mask for forming the trench 4 with using the dry etching method. Therefore, the surface of the substrate 3 is exposed. Successively, the substrate 3 is annealed at 850-1050° C. so that the substrate 3 is thermally oxidized. Thus, an oxide film 32 is formed on the surfaces of the gate electrode 6 and the substrate 3. The oxide film 32 is used as a through oxide film (i.e., a protection film) for protecting from a channeling phenomenon or contamination in a case where the P type region 7, the N⁺ type region 8 and the like are formed with using the ion implantation method in the latter process.

Then, the substrate 3 is annealed at 1170° C. in a nitrogen atmosphere during 30 minutes so as to improve the reliability of the gate insulation film 5, i.e., so as to improve quality of the film 5. Although the improvement of the gate insulation film 5 is performed in the nitrogen atmosphere, the improvement can be performed in another inert gas atmosphere.

As shown in FIG. 11B, a mask is formed with using the photolithography method. An ion implantation for implanting an impurity as a dopant and successive thermal diffusion treatment for diffusing the impurity are performed so that the P type region 7 is formed with using the mask and the gate electrode 6 as another mask. The P type region 7 becomes a channel region. The thermal diffusion treatment is performed at 1050-1100° C. so as to provide the depth of the P type region 7 from the surface of the substrate 3 to be in a range between 1.5 μm and 2 μm.

As shown in FIG. 11C, another mask is formed with using the photolithography method. The ion implantation and successive thermal diffusion treatment at 1000-1100° C. are performed so that the N⁺ type region 8 is formed with using the mask and the gate electrode 6 as another mask. The N⁺ type region 8 becomes a source region. Further, the P type body region 9 and the P⁺ type region 12 are formed.

Then, the interlayer insulation film 10 is formed on the gate electrode 6 and the substrate 3. After that, the substrate 3 is processed at 950° C. in the first reflow process (i.e., planarizing process or flattening process), so that the interlayer insulation film 10 is flattened. After that, the contact holes 13, 26, 27 are formed in the interlayer insulation film 10, and then, the substrate 3 is processed at 900° C. in the second reflow process, so that the corners of the contact holes 13, 26, 27 are rounded. Then, the metal film 11 as a source electrode is formed in the contact holes 13, 27 and on the interlayer insulation film 10. The metal film 23 as a gate electrode is formed in the contact hole 26 and on the interlayer insulation film 10.

Then, the substrate 3 is thinned with using a backside polishing method for polishing the backside of the substrate 3. After that, the metallic film 14 as a drain electrode is formed on the backside of the substrate 3. Thus, the device 100 is completed.

The characteristics of the device 100 according to the preferred embodiment are described as follows. In the process shown in FIG. 11A after the gate electrode 6 is formed, the oxide film 32 is formed on the surface of the gate electrode 6 and on the surface of the substrate 3 exposed from the oxide film 22. After that, the substrate 3 is annealed at a high temperature, which is higher than the process temperature in the thermal diffusion process for forming the N⁺ type region 8. With this high-temperature annealing process, the quality of the gate insulation film 5 is improved. Therefore, the reliability of the gate insulation film 5 is improved. Here, the reliability of the device 100 manufactured with a method according to the preferred embodiment is tested. The reliability of a comparison device manufactured with another method without annealing the substrate 3 at high-temperature after the formation of the oxide film 32 is also tested.

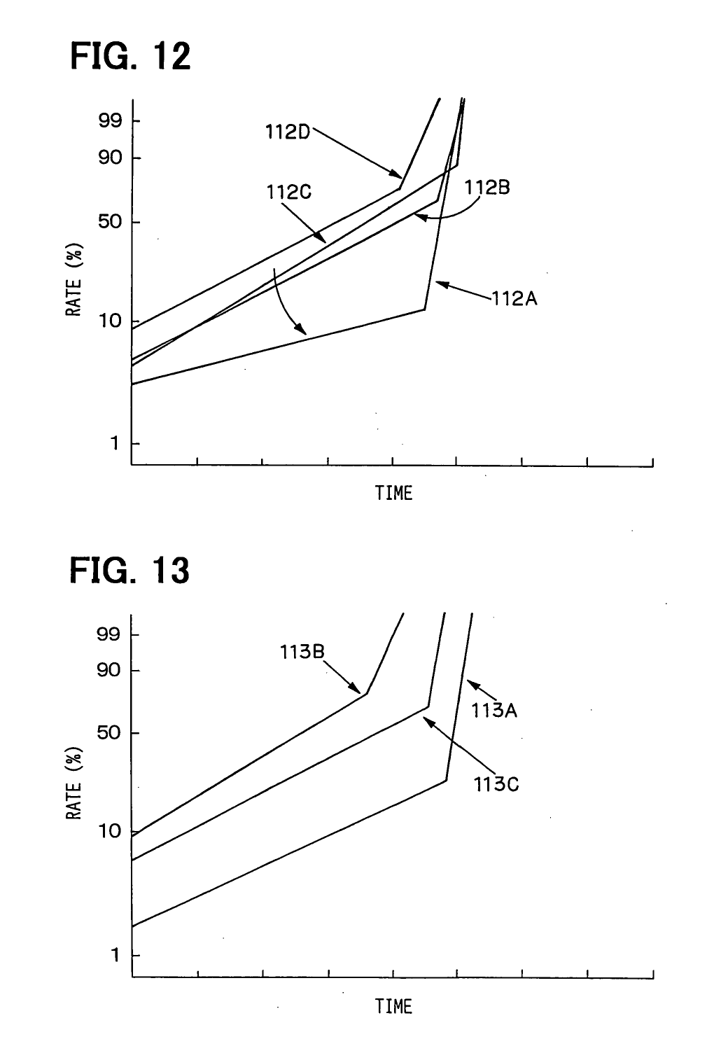

FIG. 12 shows a relationship between cumulative failure rate and fault time. FIG. 12 also shows various curves 112A-112D of the devices 100 manufactured with various methods. The curve 112A shows the device 100 manufactured with the method according to the preferred embodiment, in which the substrate 3 is annealed at 1170° C. during 30 minutes. The curve 112B shows the device 100 manufactured with a method, in which the substrate 3 is annealed at 1100° C. during 30 minutes. The curve 112C shows the device 100 manufactured with a method, in which the substrate 3 is annealed at 1050° C. during 30 minutes. The curve 112D shows the device 100 manufactured with a method, in which the substrate 3 is not annealed. Here, the test is performed at Vg=50V and 150° C.

The curve 112A is disposed lower than the curve 112D. Therefore, a random failure mode (i.e., an accidental failure) in the curve 112A is reduced, compared with the curve 112D. Specifically, the device 100 manufactured with the method according to the preferred embodiment has a low possibility of the random failure, so that the reliability of the device 100, i.e., the reliability of the gate insulation film 5 is improved. Further, the devices 100 manufactured with the methods of annealing at 1050° C. and 1100° C. shows the curves 112B and 112C, which are almost the same as the curve 112D for representing the method without annealing. Therefore, the device 100 manufactured with the method of annealing lower than 1100° C. has less reliability, so that the reliability is not improved sufficiently. Therefore, it is required to anneal higher than 1100° C.

FIG. 13 shows a relationship between cumulative failure rate and fault time. FIG. 13 also shows various curves 113A-113C of the devices 100 manufactured with various methods. The curve 113A shows the device 100 manufactured with a modified method according to the preferred embodiment, in which the substrate 3 is annealed at 1170° C. during 10 minutes after the oxide film 32 is formed on the gate electrode 6 in the process shown in FIG. 11A. The curve 113B shows the device 100 manufactured with a method, in which the substrate 3 is annealed after the gate insulation film 5 is formed on the inner wall of the trench 4 in the process shown in FIG. 9B and before the oxide film 32 is formed on the gate electrode 6 in the process shown in FIG. 11A. The curve 113C shows the device 100 manufactured with a method, in which the substrate 3 is not annealed.

The curve 113A is disposed lower than the curve 113C. Therefore, the random failure mode in the curve 112A is reduced, compared with the curve 113C. Specifically, the device 100 manufactured with the method of annealing at 1170° C. during 10 minutes has a low possibility of the random failure, so that the reliability of the device 100, i.e., the reliability of the gate insulation film 5 is improved. That is, the process time can be reduced shorter than 30 minutes. However, the device 100 manufactured with the method of annealing at 1170° C. during 10 minutes after the gate insulation film 5 is formed and before the oxide film 32 is formed on the gate electrode 6 has less reliability so that the random failure mode is not reduced sufficiently. Therefore, it is required that the annealing is performed after the oxide film 32 is formed on the gate electrode 6.

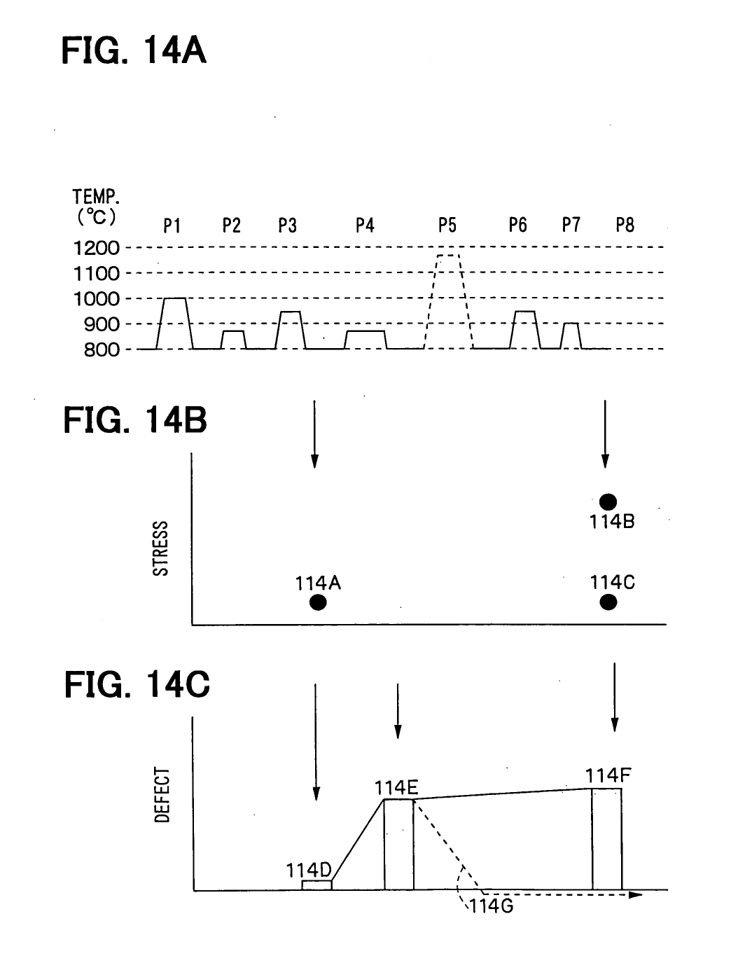

FIGS. 14A-14C show a relationship among the manufacturing process and the stress and the crystalline defect, which are generated in the substrate 3 near the trench 4. FIG. 14A shows the process temperature in each process. FIG. 14B shows a magnitude of the stress generated in the substrate 3 near the upper portion of the trench 4. FIG. 14C shows a density of the crystalline defect generated in the substrate 3 near the trench 4. In FIG. 14A, P1 represents the process of annealing after the trench 4 is formed, shown in FIG. 8A. P2 represents the process of forming the bottom oxide film 5a, shown in FIG. 8B. P3 represents the process of forming the top oxide film 5c, shown in FIG. 9B. P4 represents the process of oxidation of the gate electrode 6, shown in FIG. 11A. P5 represents the process of annealing at 1170° C., i.e., the high-temperature annealing process shown in FIG. 11A. P6 represents the first reflow process. P7 represents the second reflow process. P8 represents the process of forming the metal films 11, 23.

As shown in FIG. 14B, the stress 114B measured after the metal films 11, 23 as the gate electrode and the source electrode are formed is increased in a case where the high-temperature annealing is not performed. Specifically, the stress 114B is increased compared with the stress 114A measured after the gate insulation film 5 (i.e., the top oxide film 5c) is formed and before the gate electrode 6 is formed. By contrast, the stress 114C measured after the metal films 11, 23 are formed in a case where the high-temperature annealing is performed is almost the same as the stress 114A measured after the top oxide film 5c is formed and before the gate electrode 6 is formed.

As shown in FIG. 14C, the crystalline defect 114E generated in the substrate near the trench 4 is increased after the oxide film 32 is formed on the gate electrode 6, compared with the crystalline defect 114D measured after the ONO film 5d is formed on the inner wall. After that, the crystalline defect 114F measured after the gate insulation film 5 is formed and before the gate electrode 6 is formed in a case where the high-temperature annealing is not performed is almost the same as the crystalline defect 114E measured after the oxide film 32 is formed. By contrast, no crystalline defect 114G is observed after the metal films 11, 23 are formed in a case where the high-temperature annealing is performed.

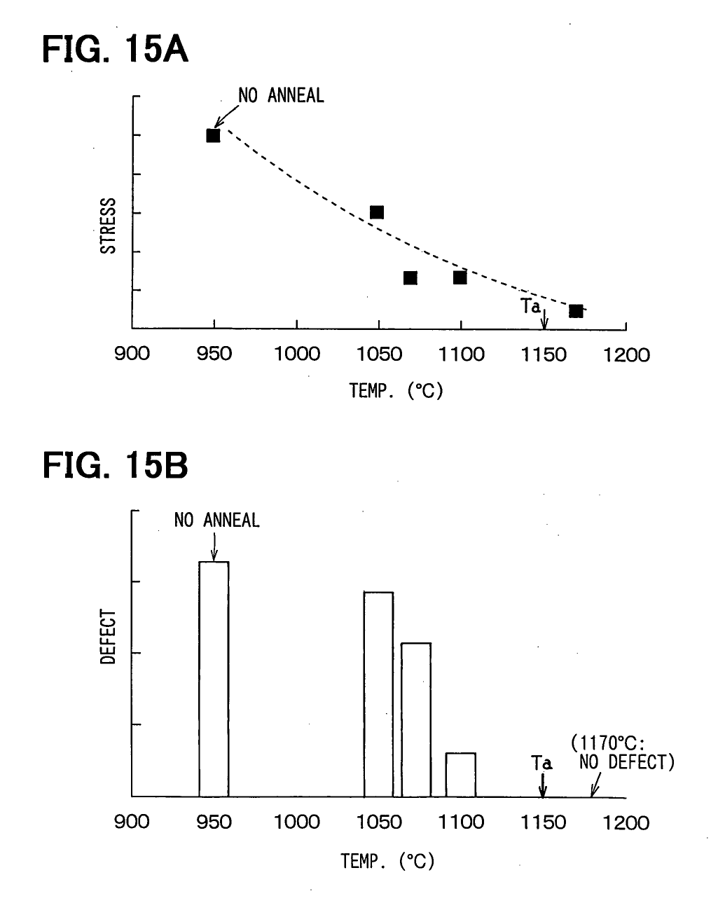

FIG. 15A shows a relationship between the process temperature and the stress generated in the substrate 3 near the upper portion of the trench 4. FIG. 15B shows a relationship between the process temperature and the crystalline defect generated in the substrate 3 near the trench 4. These relationships are obtained by the device 100 in the manufacturing process according to the preferred embodiment. Here, even if the high-temperature annealing is not performed, the first reflow process as a heat treatment is performed after the oxide film 32 is formed on the gate electrode 6. The first reflow process for planarizing the interlayer insulation film 10 is performed at 950° C. Therefore, this temperature, i.e., 950° C. represents the process temperature in a case where the high-temperature annealing is not performed.

As shown in FIGS. 15A and 15B, as the process temperature is increased, the stress and the crystalline defect are reduced.

In a case where the high-temperature annealing is not performed, the crystalline defect and the stress disposed in the substrate 3 near the trench 4 are generated after the oxide film 32 is formed on the gate electrode 6. After that, the crystalline defect and the stress remains to be disposed near the trench 4.

Therefore, the high-temperature annealing is performed after the oxide film 32 is formed on the gate electrode 6 so that the crystalline defect and the stress disposed near the trench 4 are reduced. Therefore, the gate insulation film 5 is protected from being damaged by the crystalline defect and the stress. Further, the damage such as a distortion in the gate insulation film 5 is also relaxed by the high-temperature annealing. The damage is caused by the stress and the crystalline defect generated near the trench 4. Thus, the reliability of the gate insulation film 5 is improved. In view of the above consideration, it is preferred that the annealing temperature, i.e., the process temperature at the high-temperature annealing process is set to be a certain temperature that provides to remove the stress and the crystalline defect in the substrate 3 near the trench 4 and to relax the damage in the gate insulation film 5. In general, transparent quartz (i.e., SiO₂), which is the same component as the gate insulation film 5, has the annealing point Ta of 1150° C. At the annealing point Ta, the inner distortion in the transparent quartz can be removed. Therefore, the annealing is performed equal to or higher than 1150° C. so that the inner distortion in the gate insulation film 5 is sufficiently removed. The upper limit of the annealing temperature is, for example, 1200° C., which is the maximum temperature of the semiconductor device and the withstand temperature of the substrate 3.

In the preferred embodiment, the P type region 7 as the channel region, the N⁺ type region 8 as the source region and the P type body region 9 are formed after the high-temperature annealing is performed. If the P type region 7, the N⁺ type region 8 and the P type body region 9 are formed before the high-temperature annealing is performed, dopants in the P type region 7, the N⁺ type region 8 and the P type body region 9 are diffused again so that the regions 7-9 are deformed. Specifically, the regions 7-9 are formed to have a predetermined concentration and a predetermined depth profile. Here, the depth profile is a configuration of the region 7-9, which is disposed in a predetermined depth measured from the surface of the substrate 3. However, both of the concentration and the depth profile are changed from the predetermined configuration with the high-temperature annealing, which is performed at high-temperature higher than the process temperature of thermal diffusion process for forming the regions 7-9. Therefore, after the high-temperature annealing, the regions 7-9 are formed so that the regions 7-9 have a predetermined configuration, i.e., a predetermined concentration and a predetermined depth profile.

In the preferred embodiment, the gate electrode 6 has a T-shaped cross section so that the canopy 6a of the gate electrode 6 covers the gate insulation film 5, i.e., the upper oxide film 5f, which is disposed around the opening 4a of the trench 4, when seeing from the upper viewpoint of the substrate 3. Specifically, the gate electrode 6 is formed so as to dispose the edge 6b of the canopy 6a outside of the edge of the opening 4a of the trench 4.

Thus, the gate electrode 6 covers the upper surface of the upper oxide film 5f disposed near the opening 4a of the trench 4. Therefore, the upper oxide film 5f is protected from being etched when the oxide film 22 is etched in the process shown in FIG. 10C. Specifically, the upper surface of the upper oxide film 5f is protected from being etched. Therefore, the gate insulation film 5 is protected from being damaged in case of etching the oxide film 22, so that the reliability of the gate insulation film 5 is limited from decreasing.

The length 6c between the edge 6b of the canopy 6a and the edge of the opening 4a of the trench 4 provides to form the N⁺ type region 8 as the source region that has the contact surface 8a between the N⁺ type region 8 and the P type region 7 disposed near the trench 4, which is almost parallel to the surface of the substrate 3. Thus, the contact surface 8a , i.e., a bottom of the N⁺ type region 8 is almost parallel to the surface of the substrate 3, and the bottom of the N⁺ type region 8 perpendicularly contacts the sidewall of the trench 4. And the contact surface 8a is not parallel or perpendicular to the upper portion of the trench 4 disposed near the opening 4a of the trench, so that a threshold voltage of the device 100 is limited from deviating from a predetermined voltage.

The length 6c between the edge 6b of the canopy 6a and the edge of the opening 4a of the trench 4 becomes in a range between 0.05 μm and 0.1 μm when the trench mask is removed in the process shown in FIG. 10C. Here, the length 6c is defined just after the gate electrode 6 is formed in the process shown in FIG. 10B. Therefore, the length 6c may not be in a range between 0.05 μm and 0.1 μm after the device 100 is completed. That is, the dimensions of the gate electrode 6 may be changed in a case where the gate electrode 6 is oxidized in the thermal process before and after the ion implantation.

(Modifications)

Although the gate insulation film 5 is composed of the ONO film 5d and the upper and lower oxide films 5e, 5f made of silicon oxide, the gate insulation film 5 can be composed of only the ONO film 5d. Further, the gate insulation film 5 can be composed of oxide film only or another film except for the ONO film 5d.

Although the gate electrode 6 has the T-shaped cross section, the gate electrode 6 can have an I-shaped cross section. In this case, the gate electrode 6 does not have the canopy 6a. However, the high-temperature annealing is performed after the gate electrode 6 is formed, so that the gate insulation film 5 can be improved.

Although the heat treatment is performed so as to form the P type region 7 as the channel region after the high-temperature annealing is performed, the high-temperature annealing and the heat treatment can be performed simultaneously in a case where the depth of the P type region 7 measured from the surface of the substrate 3 is deeper. Further, in that case, the P type region 7 can be preliminarily formed before the trench 4 is formed. That is because the thermal diffusion process is performed higher than 1100° C. in a case where the depth of the P type region 7 becomes deeper. Here, in the preferred embodiment, the thermal diffusion process is performed at 1050-1100° C. so that the depth of the P type region 7 becomes 1.5-2 μm.

Although the process temperature in the thermal diffusion process for forming the N⁺ type region 8 as the source region is lower than the annealing temperature in the high-temperature annealing process, the thermal diffusion process for forming the N⁺ type region 8 can be performed at 1170° C., which is the same temperature as the high-temperature annealing process. On the contrary, when the thermal diffusion process for forming the N⁺ type region 8 is performed at a high temperature such as 1170° C., the high-temperature annealing process can be performed at the same temperature as the process temperature in the thermal diffusion process.

Although the mesh structure has the hexagonal shaped mesh, the mesh structure can have another polygonal shaped mesh such as a square shaped mesh. Further, the trench gate can have a striped structure, although the trench gate has the mesh structure.

Although the device 100 includes the N channel type MOSFET, i.e., the DMOS transistor, the device 100 can include another power device having a MOS structure with a trench gate such as a P channel type MOSFET and an IGBT. The P channel type MOSFET has a different conductivity, which is opposite to the conductivity of the N channel type MOSFET. The IGBT has a substrate and drift layer having different conductivities, which are opposite to the conductivities of the substrate 3 and the N⁻ drift layer 2 in the N channel type MOSFET, respectively. Further, the device 100 can include another device having a trench capacitor, in which an upper electrode is formed in a trench in a substrate through an interlayer insulation film. Furthermore, the device 100 can include another device having a trench gate structure, in which a conductive film is formed in a trench through an insulation film.

Such changes and modifications are to be understood as being within the scope of the present invention as defined by the appended claims.

What is claimed is:

1. A method for manufacturing a semiconductor device comprising the steps of:
forming a trench having an inner wall in a substrate;
forming an insulation film on the inner wall of the trench;
forming a conductive film in the trench through the insulation film; and
annealing the substrate at an annealing temperature after the step of forming the conductive film so that a damage in the insulation film is removed at the annealing temperature.

2. The method according to claim 1, further comprising the step of:
forming a source region having a contact surface between the source region and the substrate, which is disposed near the trench and is almost parallel to the substrate,
wherein the insulation film includes an oxide-nitride-oxide film and upper and lower oxide films,
wherein the conductive film in the trench provides a gate electrode,
wherein the gate electrode includes a canopy for covering the upper oxide film so that the gate electrode has a T-shaped cross section,
wherein the canopy of the gate electrode has an edge, which is disposed at a predetermined distance from an edge of an opening of the trench, and
wherein the predetermined distance is predetermined not to prevent the source region from forming.

3. The method according to claim 1,
wherein the substrate is made of silicon, and
wherein the annealing temperature is equal to or higher than 1150° C.

4. The method according to claim 3, further comprising the step of:
forming a source region having a contact surface between the source region and the substrate, which is disposed near the trench and is almost parallel to the substrate,
wherein the insulation film includes an oxide-nitride-oxide film and upper and lower oxide films,
wherein the conductive film in the trench provides a gate electrode,
wherein the gate electrode includes a canopy for covering the upper oxide film so that the gate electrode has a T-shaped cross section,
wherein the canopy of the gate electrode has an edge, which is disposed at a predetermined distance from an edge of an opening of the trench, and
wherein the predetermined distance is predetermined not to prevent the source region from forming.

5. The method according to claim 1,
wherein the conductive film is made of doped poly crystalline silicon, and
wherein the insulation film is made of silicon oxide and silicon nitride.

6. The method according to claim 5, further comprising the step of:
forming a source region having a contact surface between the source region and the substrate, which is disposed near the trench and is almost parallel to the substrate,
wherein the insulation film includes an oxide-nitride-oxide film and upper and lower oxide films,
wherein the conductive film in the trench provides a gate electrode,
wherein the gate electrode includes a canopy for covering the upper oxide film so that the gate electrode has a T-shaped cross section,
wherein the canopy of the gate electrode has an edge, which is disposed at a predetermined distance from an edge of an opening of the trench, and
wherein the predetermined distance is predetermined not to prevent the source region from forming.

7. The method according to claim 1,
wherein the insulation film includes an oxide-nitride-oxide film and upper and lower oxide films,
wherein the trench includes a sidewall and upper and lower portions,
wherein the oxide-nitride-oxide film is disposed on the sidewall of the trench, the upper oxide film is disposed on the upper portion of the trench, and the lower oxide film is disposed on the lower portion of the trench,
wherein the oxide-nitride-oxide film includes a silicon oxide film, a silicon nitride film and another silicon oxide film, and
wherein the upper and lower oxide films are made of silicon oxide.

8. The method according to claim 7, further comprising the step of:
forming a source region having a contact surface between the source region and the substrate, which is disposed near the trench and is almost parallel to the substrate,
wherein the conductive film in the trench provides a gate electrode,
wherein the gate electrode includes a canopy for covering the upper oxide film so that the gate electrode has a T-shaped cross section,
wherein the canopy of the gate electrode has an edge, which is disposed at a predetermined distance from an edge of an opening of the trench, and
wherein the predetermined distance is predetermined not to prevent the source region from forming.

9. The method according to claim 1,
wherein the device includes a cell region and a gate lead wire region,
wherein the cell region includes a plurality of cells, each of which works as a transistor, and
wherein the gate lead wire region includes a gate lead wire.

10. The method according to claim 9,
wherein the transistor is an N channel type MOSFET, a P channel type MOSFET or an IGBT.

11. A method for manufacturing a semiconductor device comprising the steps of:
forming a trench having an inner wall in a substrate;
forming an insulation film on the inner wall of the trench;
forming a gate electrode in the trench through the insulation film;
implanting an impurity into the substrate with using the gate electrode as a mask after the step of forming the gate electrode;
performing a thermal diffusion process for diffusing the impurity so that a source region adjacent to the trench and disposed on a surface of the substrate is formed; and
annealing the substrate at an annealing temperature after the step of forming the conductive film so that a damage in the insulation film is removed at the annealing temperature.

12. The method according to claim 11,
wherein the thermal diffusion process is performed at a process temperature, and
wherein the annealing temperature in the step of annealing is higher than the process temperature in the step of performing the thermal diffusion process.

13. The method according to claim 11,
wherein the insulation film includes an oxide-nitride-oxide film and upper and lower oxide films,
wherein the trench includes a sidewall and upper and lower portions,
wherein the oxide-nitride-oxide film is disposed on the sidewall of the trench, the upper oxide film is disposed on the upper portion of the trench, and the lower oxide film is disposed on the lower portion of the trench,
wherein the oxide-nitride-oxide film includes a silicon oxide film, a silicon nitride film and another silicon oxide film, and
wherein the upper and lower oxide films are made of silicon oxide.

14. The method according to claim 13, further comprising the step of:
forming a source region having a contact surface between the source region and the substrate, which is disposed near the trench and is almost parallel to the substrate,
wherein the conductive film in the trench provides a gate electrode,
wherein the gate electrode includes a canopy for covering the upper oxide film so that the gate electrode has a T-shaped cross section,
wherein the canopy of the gate electrode has an edge, which is disposed at a predetermined distance from an edge of an opening of the trench, and
wherein the predetermined distance is predetermined not to prevent the source region from forming.

15. The method according to claim 14,
wherein the distance between the edge of the canopy and the edge of the opening of the trench is in a range between 0.05 μm and 0.1 μm.

16. The method according to claim 11,
wherein the annealing temperature in the step of annealing is equal to or higher than 1150° C., and
wherein the substrate is annealed in an inert gas atmosphere in the step of annealing.

17. A semiconductor device having a trench gate structure, comprising:
a semiconductor substrate having a trench with an inner wall disposed in the substrate;
an insulation film disposed on the inner wall of the trench;
a gate electrode disposed in the trench through the insulation film; and
a source region adjacent to the trench and disposed on a surface portion of the substrate,
wherein the insulation film does not include a damage therein.

18. The device according to claim 17,
wherein the insulation film includes an oxide-nitride-oxide film and upper and lower oxide films,
wherein the trench includes a sidewall and upper and lower portions,
wherein the oxide-nitride-oxide film is disposed on the sidewall of the trench, the upper oxide film is disposed on the upper portion of the trench, and the lower oxide film is disposed on the lower portion of the trench,
wherein the oxide-nitride-oxide film includes a silicon oxide film, a silicon nitride film and another silicon oxide film, and
wherein the upper and lower oxide films are made of silicon oxide.

19. The device according to claim 18,
wherein the gate electrode includes a canopy for covering the upper oxide film so that the gate electrode has a T-shaped cross section, and
wherein the canopy of the gate electrode has an edge, which is disposed at a predetermined distance from an edge of an opening of the trench.

20. The device according to claim 19,
wherein the source region is prepared in such a manner that an impurity is implanted into the substrate with using the gate electrode as a mask, and then the impurity is diffused with a thermal diffusion process,
wherein the damage in the insulation film is eliminated in such a manner that the insulation film is annealed at an annealing temperature after the gate electrode is formed, and
wherein the predetermined distance is predetermined not to prevent the source region from forming.

21. The device according to claim 20,
wherein the substrate is made of silicon, and
wherein the annealing temperature is equal to or higher than 1150° C.

22. The device according to claim 17,
wherein the gate electrode is made of doped poly crystalline silicon, and
wherein the insulation film includes a silicon oxide film and a silicon nitride film.

23. The device according to claim 17,
wherein the insulation film includes an oxide-nitride-oxide film and upper and lower oxide films,
wherein the trench includes an sidewall and upper and lower portions,
wherein the oxide-nitride-oxide film is disposed on a sidewall of the trench, the upper oxide film is disposed on an upper portion of the trench, and the lower oxide film is disposed on a lower portion of the trench,
wherein the oxide-nitride-oxide film includes a silicon oxide film, a silicon nitride film and another silicon oxide film, and
wherein the upper and lower oxide films are made of silicon oxide.

24. The device according to claim 17, further comprising:
a cell region and a gate lead wire region,
wherein the cell region includes a plurality of cells, each of which works as a transistor, and
wherein the gate lead wire region includes a gate lead wire.

25. The method according to claim 24,
wherein the transistor is an N channel type MOSFET, a P channel type MOSFET or an IGBT.
